(19) United States
(12) Patent Application Publication
(10) Pub. No.: US 2007/0096948 A1
(43) Pub. Date: May 3, 2007

(54) Remote communication device for use with watercraft towing a secondary recreation apparatus priority

(76) Inventor: Joseph A. La Barbera, Barneveld, NY (US)

Correspondence Address: DILWORTH & BARRESE, LLP, 333 EARLE OVINGTON BLVD., SUITE 702, UNIONDALE, NY, 11553, US

(21) Appl. No.: 11/591,136

(22) Filed: Nov. 1, 2006

Related U.S. Application Data
(60) Provisional application No. 60/732,259, filed on Nov. 1, 2005.

(51) Int. Cl. H03M 11/00

(52) U.S. Cl. 341/22

(57) ABSTRACT

Provided is a communication system to be used between a watercraft towing a remote individual and the remote individual, the communication system including a transmitter unit for transmitting a wireless signal indicating the remote individual's desired condition to the watercraft towing the remote individual; a key pad for providing tactile indications; a receiver unit located on the watercraft towing the remote individual for receiving the remote individual's transmitted wireless signals; a display unit for displaying corresponding lighted signals indicating the remote individual's desired condition; and a speaker, on the watercraft towing the remote individual, for outputting the associated alarm sound for the remote individual's desired condition.

### PRIORITY

This application claims priority to U.S. Provisional Application No. 60,732,259 filed in the United States Patent and Trademark Office on Nov. 1, 2005, the contents of which are incorporated herein by reference.

### BACKGROUND OF THE INVENTION

1. Field of the Invention

The present invention relates generally to a communication devices to be used with recreational vehicles, and in particular, to a communication system between a watercraft and a remote individual.

2. Description of the Related Art

In recent years, there has been a surge in the popularity of water skiing and other similar types of recreational activity. Laws require that there be a “spotter” in addition to a driver of a watercraft towing a remote individual, such as a skier, to provide communication between the watercraft and the remote individual being towed. However, there commonly is a problem with this communication due to a number of factors, including, but not limited to, noise produced by the motor of the towing watercraft as well as noise caused by the rush of water, thereby making it difficult for vocal communication to occur between the remote individual and the spotter on the watercraft. Therefore, several devices have been used for improving communication between the watercraft and the remote individual.

In the conventional art the device is generally located in the handle of the towrope for facilitating communication between the watercraft towing the remote individual and the remote individual, such as disclosed in U.S. Pat. No. 6,603,402. However, in the conventional art the remote individual is required to view colorcoded control buttons embedded or locatable under the surface of the tow bar handle for selection of a desired condition. Thus, it is difficult and sometimes dangerous for the remote individual while water skiing to communicate with the watercraft due to the necessity of viewing the buttons of the towrope handle for selection of a desired condition.

Therefore, there exists a need for a device which permits a remote individual to communicate with a watercraft towing the remote individual without having to view the buttons of the towrope handle for selection of a desired condition.

### SUMMARY OF THE INVENTION

It is therefore, an object of the present invention to provide a communication device that enables a remote individual to communicate with a watercraft towing the remote individual through actuation of a wireless signal for indicating to the watercraft the remote individual's desired condition by selection of one of a plurality of keys on a keypad without having to view the keypad for selecting the desired condition. The present invention enables a remote individual to notify the watercraft of the desired conditions, such as to go faster, to slow down, to stop, and to return to shore by selection of a key that projects above the keypad surface on a towrope handle for actuating wireless transmitter signals.

In accordance with the present invention, there is provided a communication device for communication between a watercraft towing a remote individual and the remote individual, including a transmitter unit for transmitting a wireless signal indicating the remote individual's desired condition to a receiver unit located on the watercraft towing the remote individual; and a keypad having a plurality of keys for providing tactile indication of a key which can transmit a signal indicative of the remote individual's desired condition. The remote individual's desired condition includes at least one of a faster, a slower, a return to shore and a stop condition.

In another aspect of the present invention, there is provided keys of a keypad that project out from the surface of a tow rope handle for permitting the remote individual to select the desired condition without having to view the same while being towed.

In yet another aspect of the present invention, there is provided a communication system to be used between a watercraft towing a remote individual and the remote individual, the communication system including a transmitter unit for transmitting a wireless signal indicating the remote individual's desired condition to the watercraft towing the remote individual; a key pad providing tactile indications of the remote individual's desired condition for actuating the transmitter and generating a wireless signal indicative of the desired condition; a receiver unit located on the watercraft towing the remote individual for receiving the remote individual's transmitted wireless signals; a display unit for displaying, on the watercraft towing the remote individual, corresponding lighted signals with associated sounds for indicating the remote individual's desired condition based on the received signals; and a speaker, on the watercraft towing the remote individual, for outputting the associated sound.

### BRIEF DESCRIPTION OF THE DRAWINGS

The above and other objects features and advantages of the present invention will become more apparent from the following detailed description when taken in conjunction with the accompanying drawings in which:

FIG. 1 is a pictorial view illustrating a communication system of the present invention;

FIG. 2 illustrates a towrope handle showing keys of a keypad;

FIG. 3 illustrates a towrope handle showing keys with tactile indicators of a keypad selection of desired condition by a user;

FIG. 4 illustrates the towrope handle in a partial cut-away view, showing the various components therein; and

FIG. 5 is a block diagram illustrating the circuit of the communication system according to the present invention.

### DETAILED DESCRIPTION OF THE PREFERRED EMBODIMENT

A preferred embodiment of the present invention will now be described in detail with reference to the annexed drawings. However, the invention can be embodied in different forms, and in the following description, a detailed description of well-known functions and constructions incorporated herein has been omitted since they are clearly understood in the art upon consideration of the present disclosure.

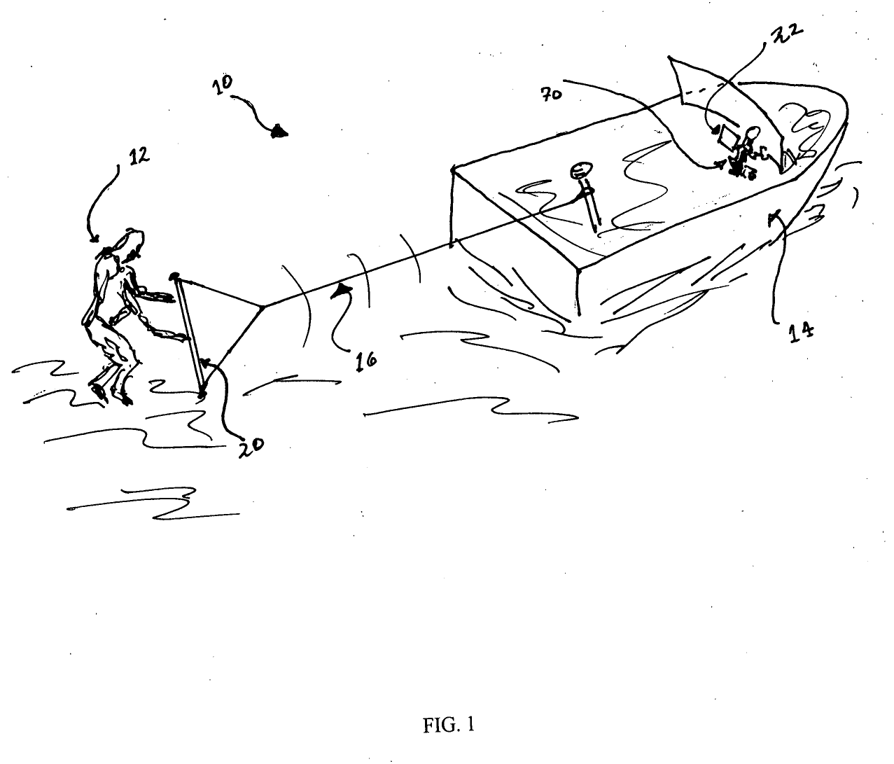

FIG. 1 is a pictorial view illustrating a communication system 10 of the present invention. Referring to FIG. 1, shown is a watercraft 14 towing, via a towrope 16, a remote individual 12 such as a water skier, wherein the remote individual 12 is holding onto a towrope handle 20 secured to the towrope 16. A communication device 22, as shown in FIG. 1, is located on the watercraft 14 towing the remote individual 12 and receives wireless signals transmitted from a transmitter located within the towrope handle 20 in response to the remote individual's actuation of a desired condition.

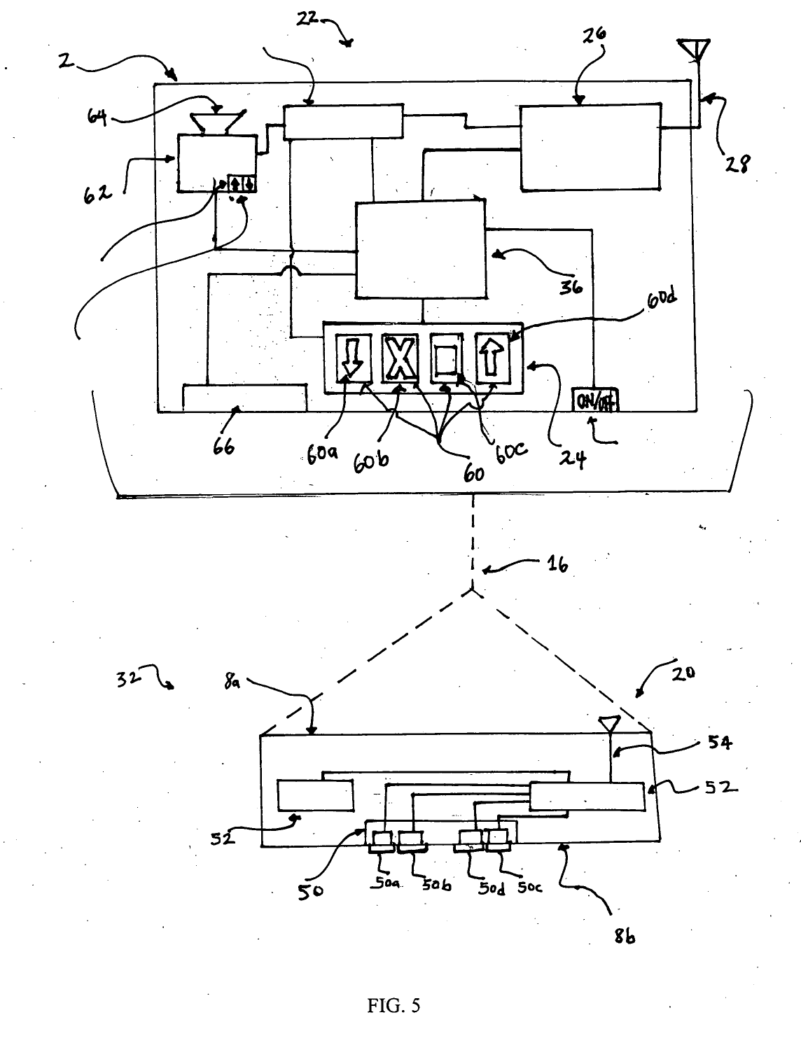

FIG. 5 is a block diagram illustrating the circuit of the communication system according to the present invention. Referring to FIG. 5, the communication device 22 includes a Liquid Crystal Display (LCD) unit 24 that is operative with a wireless receiver unit 26, which receives signals via antenna 28. The LCD unit 24 includes corresponding indicators 60, such as lights, for indicating the remote individual's desired condition that are actuated via a control unit 36, which can be a microprocessor, via wireless transmitter signals from a transmitter unit 52 located in the towrope handle 20. The wireless transmitter unit 52 signals are indicative of the remote individual's desired condition. The communication device 22, as shown in FIG. 5, is preferably waterproof to prevent water infiltration as would any marine type electronic device.

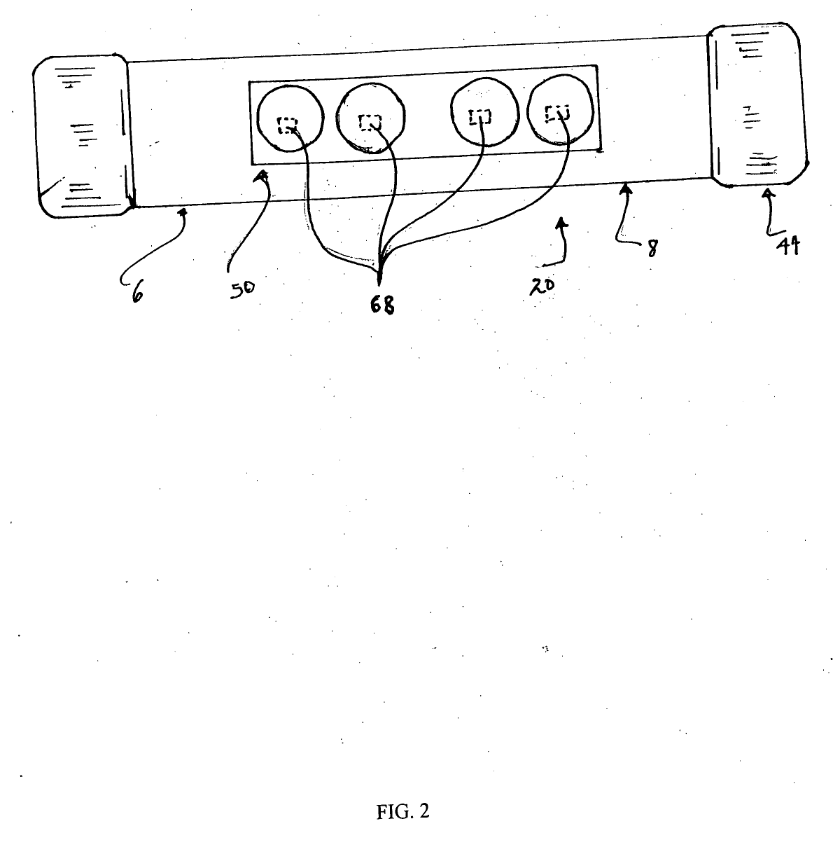

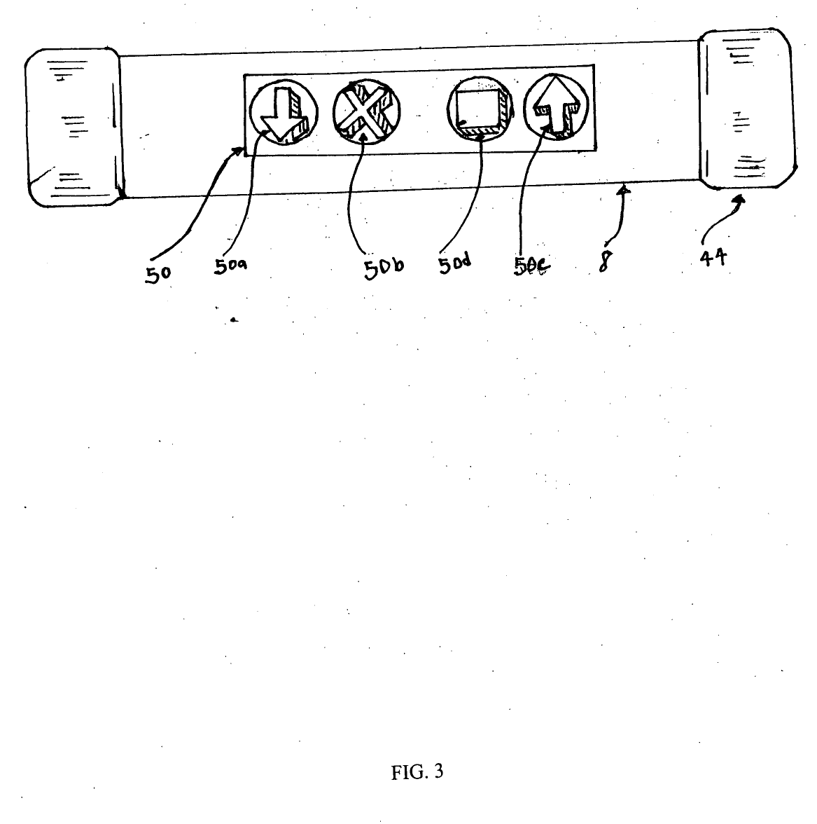

The remote individual's towrope handle 20 is preferably cylindrically configured to which a towrope 16 is secured at both ends for towing the remote individual 12. Referring to FIGS. 2 and 3, the towrope handle 20 is provided with a surface having a grip portion 8 that can be formed from non-slip material, such as rubber, which the remote individual can grasp while water skiing. The material is formed over the cylindrically shaped body member 6 that contains the various components of the towrope handle 20.

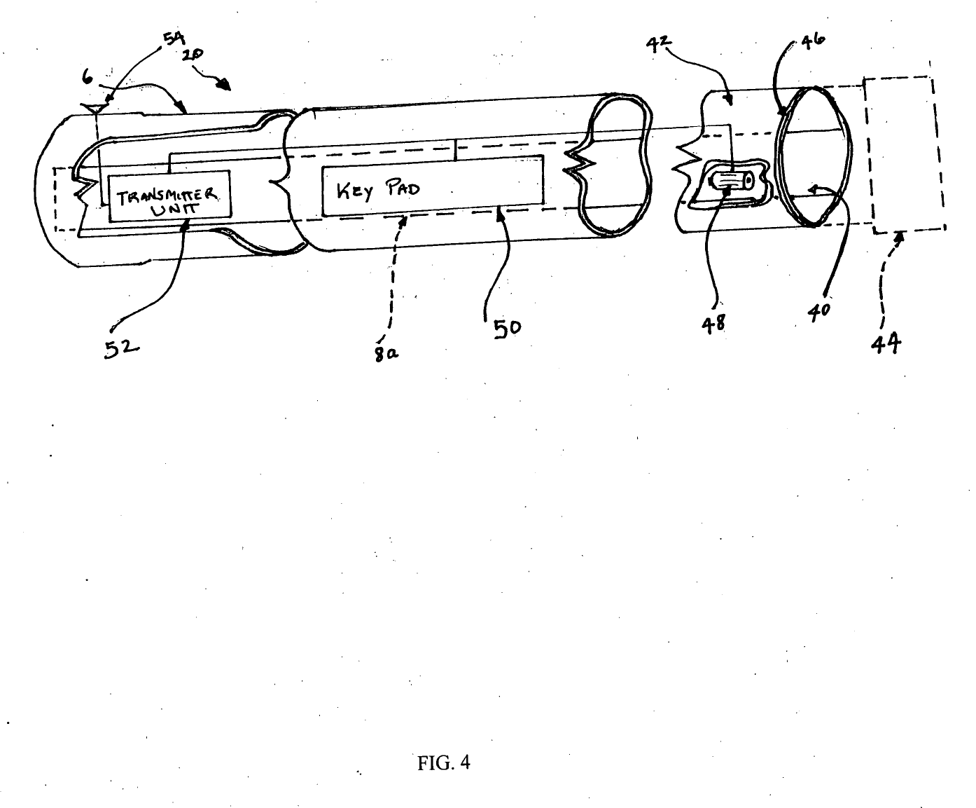

As shown in FIG. 4, the towrope handle 20 has at least one open end 40, which defines a battery compartment 42 contained in the interior of the body member 6. A removable battery compartment cover 44 is formed as a screw type end cap with a gasket, for mounting to the open end 40 of the towrope handle 20 for accessing and installing one of a replaceable battery and a rechargeable battery pack 48. The battery compartment cover 44 is water sealed when positioned over the open end 40 with sealingly engaging threads 46 of the towrope handle 20.

The grip portion 8 includes a front grip portion 8a and a rear grip portion 8b. Along the rear grip portion 8b is a keypad 50 preferably having four keys 50a, 50b, 50c and 50d that project out and above the surface of the key pad 50, facing the remote individual 12, for providing tactile indications of the remote individual's desired condition, such as to go faster, to go slower, return to shore and stop. The raised key allows the individual to “feel” for particular key, to transmit a signal indicative of his condition. The remote individual's selection of a desired condition by exertion of pressure on one of the four keys 50a, 50b, 50c and 50d actuates a transmitter unit 52, which generates wireless signals indicative of the desired conditions of the remote individual. As illustrated keys 50a and 50b are configured as a down arrow to indicate go slower and an “X” to indicate stop, respectively, and are located leftmost of the key pad 50 for selection by the remote individual 12 with a simple movement of, for example, the left thumb. Keys 50c and 50d are configured as an up arrow to indicate go faster and a square symbol to indicate return to shore, respectively, and are located rightmost of the key pad 50 for selection by the remote individual 12 with a simple movement of, for example, the right thumb. Although four keys are shown, it is contemplated that any number of keys having tactile indicators may be provided.

The keys 50a, 50b, 50c and 50d project out from the surface of the key pad 50 to facilitate easy selection by the remote individual merely by feeling by way of touch for a desired condition without having to actually view keys 50a, 50b, 50c and 50d for selection. Thereby, the remote individual 12 can recognize the specific tactile indications of keys 50a, 50b, 50c and 50d by touch without having to ever view same while water skiing.

As shown in FIG. 4, the wireless transmitter 52 is sealed in the watertight compartment of the towrope handle 20 and is operatively connected to the battery mounted within the battery compartment 42. The actuation of the keys 50a, 50b, 50c and 50d by exertion of pressure is for generating and transmitting wireless signals to communication device 22 to communicate the remote individual's desired condition. An antenna 54 is operatively connected to the transmitter unit 52.

The communication device 22 is provided with a display unit 24 for indicating the remote individual's desired condition upon receipt of a transmitted signal. In the present invention, the display unit 24 is configured as a Liquid Crystal Display (LCD) and includes indicators 60, such as icons 60a, 60b, 60c and 60d for indicating the condition of the remote individual. Icons 60a, 60b, 60c and 60d include an up arrow for go faster, an “X” for stop, a square symbol for return to shore and down arrow for go slower, respectively.

The indicators 60, e.g., the icons 60a, 60b, 60c and 60d can be alternately constructed with LED's and can be color coded for easy recognition. For example, the down arrow icon 60a for slow down can be the color yellow and can light up when the remote individual actuates the corresponding key of the key pad 50 for selection of the desired condition. The “X” icon 60b for stop can be red, the square symbol icon 60c for return to shore can be blue and the up arrow icon 60d for go faster can be green. Further, each icon can blink a selected number of times to aid in capturing the attention of the operator 70 (FIG. 1) of the watercraft and for permitting the operator to observe that a desired condition has changed.

In a further aspect of the present invention, there is provided an alarm 62 that can correspondingly sound for a selected number of seconds for each icon, for indicating the remote individual's condition. Each icon 60a, 60b, 60c and 60d displayed on the display unit 24 can have its own distinctive tone or series of tones upon generation of an alarm. Coupled to the alarm 62 is a speaker 64 for outputting an alarm sound. The sounding of alarm 62 enables the operator of the watercraft to determine the remote individual's desired condition without having to actually view the display unit 24.

As shown in FIG. 5, the communication device 22 includes a housing 2 which is preferably waterproof to prevent water infiltration as would any marine electronics device (e.g., radio, CB, etc.). The housing 2 supports the LCD display unit 24 with the various icons 60a, 60b, 60c and 60d for indicating the remote individual's desired condition. The wireless receiver unit 26 is connected to an antenna 28 for receiving wireless signals transmitted from the towrope handle 20 upon actuation of keys 50a, 50b, 50c and 50d of the key pad 50 for indicating the remote individual's desired condition. The housing 2 contains a control unit 36 connected to the wireless receiver 26 and the display unit 24 for generating the appropriate signal for controlling the display unit 24 for displaying the proper icons to indicate the remote individual's desired condition. Provided also is a series of programming buttons 66, as shown, that are operatively connected to the control unit 36 for allowing the user to selectively program the display and the alarm for correspondingly displaying the different icons 60a, 60b, 60c and 60d and sounding the different audible alarms for indicating the remote individual's desired condition.

The present invention provides a means for communication to be used between a watercraft towing a remote individual and the remote individual. The communication system allows the remote individual, while being towed, to select without viewing the key pad located on the grip portion of the towrope handle one of four keys having tactile indications, such as an up arrow, a down arrow, an “X” and a square symbol, by feeling and exerting pressure for actuating the wireless transmitter located therein for transmitting wireless signals to a wireless receiver located in a communication device located on the watercraft for indicating the remote individual's desired condition, such as to go faster, slower, stop and return to shore. The four keys of the keypad project out and above the surface for easy selection by tactile feel to indicate the remote individual's desired condition without having to view same for selection.

While the present invention has been shown and described with reference to certain preferred embodiments thereof, it will be understood by those skilled in the art that various changes in form and details may be made therein without departing from the spirit and scope of the invention as defined by the appended claims.

What is claimed is:

1. A communication device for communication between a watercraft towing a remote individual and the remote individual, comprising:
a transmitter unit for transmitting a wireless signal indicating the remote individual's desired condition to a receiver unit located on the watercraft towing the remote individual; and
a keypad for providing tactile indication of the remote individual's desired conditions.

2. A communication device according to claim 1, wherein the remote individual's desired conditions comprise at least one of a faster, a slower, a return to shore and a stop condition.

3. A communication device according to claim 1, wherein the keypad has keys that project above the surface of the keypad for selection by the tactile indication of the remote individual's desired conditions.

4. A communication device according to claim 1, wherein the tactile indications for indicating the remote individual's desired condition comprise a different symbol projecting out of the surface of the keypad for each desired condition including an “up arrow” for faster, a “down arrow” for slower, a “square” for return to shore and an “X” symbol for stop.

5. A communication device according to claim 3, wherein the four keys are situated facing the remote individual, and two of the four keys are located closest to the right thumb of the individual, and two keys are located closest to the left thumb of the individual for selection without having to view same for selection.

6. A communication device according to claim 1, wherein the tactile indications for indicating the remote individual's desired condition are responsive to pressure exerted by the remote individual.

7. A communication system to be used between a watercraft towing a remote individual and the remote individual, the communication system comprising:
a transmitter unit for transmitting a wireless signal indicating the remote individual's desired condition to the watercraft towing the remote individual;
a key pad providing tactile indications of the remote individual's desired condition for actuating the transmitter unit and generating a wireless signal indicative of the desired condition;
a receiver unit located on the watercraft towing the remote individual for receiving wireless signals transmitted from the remote individual;
a display unit for displaying, on the watercraft towing the remote individual, corresponding lighted signals with associated sounds for indicating the remote individual's desired condition based on the wirelessly received signals indicating the remote individual's desired condition; and
a speaker, on the watercraft towing the remote individual, for outputting the associated sound for the remote individual's desired condition.

8. A communication system according to claim 7, wherein the display unit displays the corresponding lighted signals for a preset period.

9. A communication system according to claim 7, wherein the remote individual's desired conditions comprise at least one of a faster, a slower, a return to shore and a stop condition.

10. A communication system according to claim 7, wherein the keypad has four keys that are projected out and above the surface of the keypad to provide tactile indications of the remote individual's desired conditions.

11. A communication system according to claim 10, wherein the four keys for providing the tactile indications, comprise a different symbol for each condition including an “up arrow” for faster, a “down arrow” for slower, a “square” for return to shore and an “X” symbol for stop.

12. A communication system according to claim 10, wherein the four keys are situated facing the remote individual, and two of the four keys are located closest to the right thumb while two keys are located closest to the left thumb for selection without having to view same.

13. A communication device according to claim 7, wherein the tactile indications for indicating the remote individual's desired condition are responsive to pressure exerted by the remote individual.

14. A communication system according to claim 11, wherein the speaker outputs a different sound for indicating each of the remote individual's desired conditions for a preset period.
